(19) United States
(12) Patent Application Publication
(10) Pub. No.: US 2022/0310505 A1
(43) Pub. Date: Sep. 29, 2022

(54) SEMICONDUCTOR MEMORY DEVICE

(71) Applicant: Kioxia Corporation, Tokyo (JP)

(72) Inventor: Hiroyuki HAMA, Yokkaichi (JP)

(73) Assignee: Kioxia Corporation, Tokyo (JP)

(21) Appl. No.: 17/447,496

(22) Filed: Sep. 13, 2021

(30) Foreign Application Priority Data
Mar. 23, 2021 (JP) 2021-048271

(51) Int. Cl. H01L 23/528; H01L 23/522; H01L 27/11556; H01L 27/11582

(52) U.S. Cl. CPC H01L 23/528; H01L 23/5226; H01L 27/11556; H01L 27/11582

(57) ABSTRACT

A semiconductor memory device of an embodiment includes: a first stacked body in which a plurality of first conductive layers is stacked via a first insulating layer; a second stacked body in which a plurality of second insulating layers is stacked via the first insulating layer, the second stacked body being surrounded by the first stacked body; and a pair of first plate-like portions extending in a stacking direction and in a first direction intersecting the stacking direction, the pair of first plate-like portions being disposed between the first and second stacked bodies on both sides of the second stacked body in a second direction intersecting the stacking direction and the first direction. The pair of first plate-like portions each has a first side wall facing the first stacked body and including a metal element-containing layer in contact with an end surface of the first insulating layer of the first stacked body.

### CROSS-REFERENCE TO RELATED APPLICATIONS

This application is based upon and claims the benefit of priority from Japanese Patent Application No. 2021-048271, filed on Mar. 23, 2021; the entire contents of which are incorporated herein by reference.

### FIELD

Embodiments described herein relate generally to semiconductor memory devices.

### BACKGROUND

In a manufacturing process of a semiconductor memory device such as a three-dimensional nonvolatile memory, a stacked body of conductive layers is formed by, for example, replacing a plurality of insulating layers with conductive layers. For example, in order to pass a contact connecting the upper and lower structures of the stacked body, a part of the stacked body may be maintained as insulating layers without being replaced with conductive layers.

### BRIEF DESCRIPTION OF THE DRAWINGS

FIGS. 1A and 1B are diagrams illustrating a schematic configuration example of a semiconductor memory device according to a first embodiment;

FIGS. 2A to 2C are cross-sectional views along the Y direction illustrating a detailed configuration example of the semiconductor memory device according to the first embodiment;

FIGS. 3A to 3C are cross-sectional views along the Y direction illustrating an example of the procedure of the method of manufacturing the semiconductor memory device according to the first embodiment;

FIGS. 4A to 4C are cross-sectional views along the Y direction illustrating an example of the procedure of the method of manufacturing the semiconductor memory device according to the first embodiment;

FIGS. 5A to 5C are cross-sectional views along the Y direction illustrating an example of the procedure of the method of manufacturing the semiconductor memory device according to the first embodiment;

FIGS. 6A to 6C are cross-sectional views along the Y direction illustrating an example of the procedure of the method of manufacturing the semiconductor memory device according to the first embodiment;

FIGS. 7A to 7C are cross-sectional views along the Y direction illustrating an example of the procedure of the method of manufacturing the semiconductor memory device according to the first embodiment;

FIGS. 8A to 8C are cross-sectional views along the Y direction illustrating an example of the procedure of the method of manufacturing the semiconductor memory device according to the first embodiment;

FIGS. 9A and 9B are cross-sectional views along the Y direction illustrating a configuration example of a plate-like portion provided in the semiconductor memory device according to modifications of the first embodiment;

FIGS. 10A to 10C are cross-sectional views along the Y direction illustrating an example of the procedure of the method of manufacturing the semiconductor memory device according to a second embodiment; and

FIGS. 11A to 11C are cross-sectional views along the Y direction illustrating an example of the procedure of the method of manufacturing the semiconductor memory device according to the second embodiment.

### DETAILED DESCRIPTION

A semiconductor memory device of an embodiment includes: a first stacked body in which a plurality of first conductive layers is stacked via a first insulating layer; a second stacked body in which a plurality of second insulating layers is stacked via the first insulating layer, the second stacked body being surrounded by the first stacked body as viewed from a stacking direction of each layer of the first stacked body; a pair of first plate-like portions extending in the stacking direction and in a first direction intersecting the stacking direction, the pair of first plate-like portions being disposed between the first and second stacked bodies on both sides of the second stacked body in a second direction intersecting the stacking direction and the first direction; and a pair of second plate-like portions extending in the first direction, the pair of second plate-like portions sandwiching the pair of first plate-like portions from both sides in the second direction at a position apart from the pair of first plate-like portions, the pair of second plate-like portions extending in the stacking direction in the first stacked body. The pair of first plate-like portions each has a first side wall facing the first stacked body and including a metal element-containing layer in contact with an end surface of the first insulating layer of the first stacked body.

The present invention will be described below in detail with reference to the drawings. Note that the present invention is not limited to the following embodiments. The components in the following embodiments include those that can be readily assumed by those skilled in the art or those that are substantially identical.

### First Embodiment

The first embodiment will be described below in detail with reference to the drawings.

(Configuration Example of Semiconductor Memory Device)

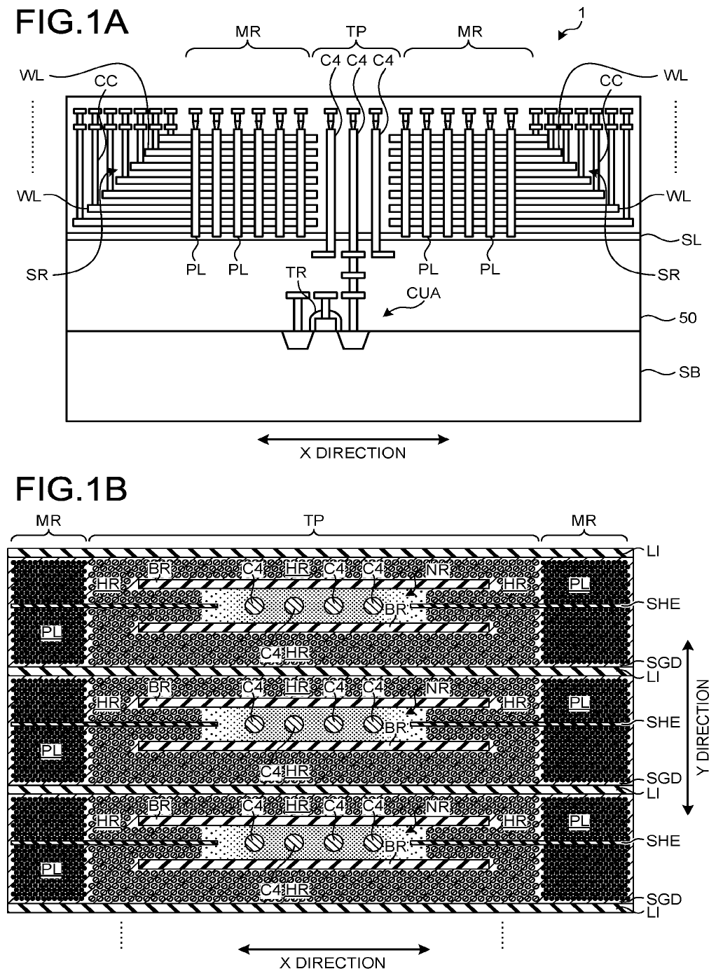

FIGS. 1A and 1B are diagrams illustrating a schematic configuration example of a semiconductor memory device 1 according to the first embodiment. FIG. 1A is a cross-sectional view along the X direction illustrating a schematic configuration of the semiconductor memory device 1, and FIG. 1B is a cross-sectional view of a region including a through contact region TP of the semiconductor memory device 1. In FIG. 1A, however, hatching is omitted for ease of viewing the drawing. In FIG. 1A, a part of an upper layer wiring is omitted.

In the present description, both the X direction and the Y direction are directions along the direction of the plane of a word line WL to be described below, and the X direction and the Y direction are orthogonal to each other. The electrical lead-out direction of the word line WL to be described below is sometimes referred to as a first direction, and the first direction is a direction along the X direction. The direction intersecting the first direction is sometimes referred to as a second direction, and the second direction is a direction along the Y direction. However, since the semiconductor memory device 1 may include variation in manufacturing, the first direction and the second direction are not necessarily orthogonal to each other.

As illustrated in FIGS. 1A and 1B, the semiconductor memory device 1 includes a peripheral circuit CUA, a memory region MR, a through contact region TP, and a stepped region SR on a substrate SB.

The substrate SB is, for example, a semiconductor substrate such as a silicon substrate. The peripheral circuit CUA including a transistor TR and wiring is disposed on the substrate SB. The peripheral circuit CUA contributes to the operation of a memory cell to be described below.

The peripheral circuit CUA is covered with an insulating layer 50. On the insulating layer 50, a source line SL is disposed. A plurality of conductive layers is stacked above the source line SL, and at least a part of the conductive layers functions as the word line WL.

The word lines WL as a plurality of first conductive layers each extend along the X direction and are divided in the Y direction by a plurality of contacts LI arranged in the Y direction. In other words, each of the plurality of contacts LI extends along the X direction along the planes of the word lines WL and penetrates the word lines WL in the stacking direction.

Between two adjacent contacts LI as a pair of second plate-like portions, a plurality of memory regions MR, a through contact region TP including an insulating region NR, and stepped regions SR each formed at both end portions of the word line WL are disposed.

Between the two contacts LI, a separation layer SHE is disposed to separate one or more conductive layers including at least the uppermost conductive layer out of the plurality of conductive layers described above, stacked above the source line SL. The separation layer SHE extends along the X direction in the memory region MR, and regions of the through contact region TP other than the insulating region NR. The separation layer SHE may extend to the stepped regions SR at the both end portions of the word lines WL.

A selection gate line SGD as the first conductive layer is patterned by the separation layer SHE penetrating one or more conductive layers including the uppermost conductive layer. In other words, the separation layer SHE partitions the one or more conductive layers to be stacked into a pattern of selection gate lines SGD disposed on both sides in the Y direction of the separation layer SHE. FIG. 1B illustrates a cross section at the height position of the selection gate line SGD of the semiconductor memory device 1.

In the memory region MR, a plurality of pillars PL is disposed which penetrates the word lines WL in the stacking direction. A plurality of memory cells is formed at the intersections of the pillar PL and each of the word lines WL. Thus, the semiconductor memory device 1 is configured as a three-dimensional nonvolatile memory in which memory cells are three-dimensionally arranged in the memory region MR, for example. At the upper end portion of the pillar PL, a plug is disposed which connects the pillar PL to the upper layer wiring such as a bit line.

The stepped region SR has a configuration in which a plurality of word lines WL is led out in a stepped manner. At each terrace portion of the plurality of word lines WL led out in a stepped manner, a contact CC is disposed which connects, for example, the word line WL to the upper layer wiring. In the present description, the direction in which the terrace surface of each step of the stepped region SR faces is defined as the upward direction.

The through contact region TP is disposed in a region sandwiched in the X direction by the memory region MR, for example, between two adjacent contacts LI. The through contact region TP is disposed with an insulating region NR, plate-like portions BR, a plurality of contacts C4, and a plurality of columnar portions HR.

The insulating region NR is surrounded by a plurality of stacked word lines WL when viewed from the stacking direction of the word lines WL. In the insulating region NR, the word line WL is not disposed, but multiple types of insulating layers are stacked.

The plate-like portions BR as a pair of first plate-like portions are disposed on both sides in the Y direction of the insulating region NR so as to extend along the X direction. In other words, each of the plate-like portions BR extends in the direction along the X direction and in the stacking direction of the word lines WL on both sides of the insulating region NR. However, regardless of the examples of FIGS. 1A and 1B, the plate-like portion BR may have other shapes and arrangements if the insulating region NR can be sufficiently separated from other regions.

Between the two plate-like portions BR, a contact C4 is disposed which connects, for example, the peripheral circuit CUA disposed on the lower substrate SB and various upper layer wirings.

In the example of FIGS. 1A and 1B, a plurality of contacts C4 arranged in the X direction is disposed in the insulating region NR. However, only one contact C4 may be disposed in the insulating region NR. Alternatively, the plurality of contacts C4 may also be arranged in the Y direction instead of or in addition to the X direction.

Such the contact C4 allows the configuration of, for example, the pillar PL and the word line WL to be connected to the peripheral circuit CUA via the upper layer wiring.

The plurality of columnar portions HR is disposed dispersedly in the through contact region TP except the periphery of the contact C4. Each of the columnar portions HR penetrates the word lines WL in the stacking direction, and functions as a strut supporting the stacked structure of the semiconductor memory device 1 in the manufacturing process of the semiconductor memory device 1 to be described below.

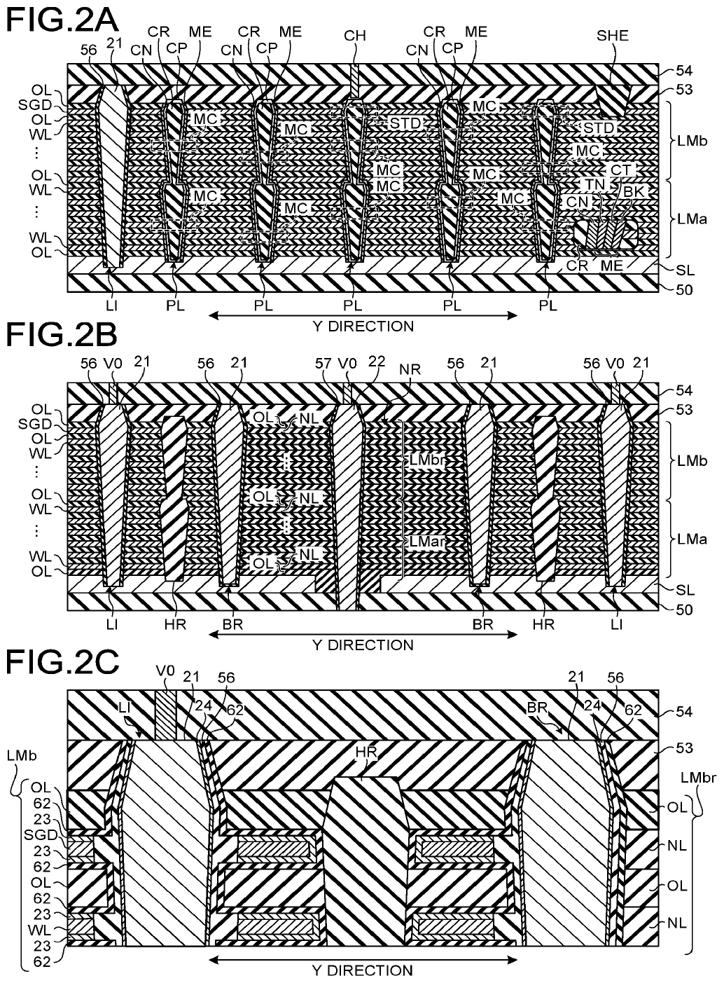

FIGS. 2A to 2C are cross-sectional views along the Y direction illustrating a detailed configuration example of the semiconductor memory device 1 according to the first embodiment. FIG. 2A is a partial cross-sectional view including one contact LI in the memory region MR, and FIG. 2B is a partial cross-sectional view illustrating a pair of contacts LI in the through contact region TP. FIG. 2C is an enlarged cross-sectional view illustrating an area between one contact LI and one plate-like portion BR in the through contact region TP. In FIGS. 2A to 2C, the peripheral circuit CUA and a part of the upper layer wiring are omitted.

As illustrated in FIGS. 2A and 2B, a stacked body LMa is disposed on the source line SL, and a stacked body LMb is disposed on the stacked body LMa.

Both of the stacked bodies LMa and LMb as the first stacked body have a configuration in which the word lines WL as the plurality of first conductive layers are stacked via an insulating layer OL as the first insulating layer. The number of stacked layers of the word lines WL in the stacked bodies LMa and LMb is arbitrary.

The stacked body LMb includes one or more selection gate lines SGD as the first conductive layer on the uppermost word line WL via the insulating layer OL as the first insulating layer. In other words, as described above, the selection gate line SGD is patterned by the separation layer SHE penetrating one or more conductive layers including the uppermost conductive layer of the stacked body LMb. The separation layer SHE is an insulating layer such as a SiO₂ layer, for example, and thereby separates the selection gate line SGD in the Y direction.

The stacked body LMa may include one or more selection gate lines as the first conductive layer, below the lowermost word line WL.

The word line WL and the selection gate line SGD are, for example, a tungsten layer or a molybdenum layer. The word line WL and the selection gate line SGD may be made of different conductive materials. In such a case, the selection gate line SGD may be, for example, a polysilicon layer. The insulating layer OL is, for example, a SiO₂ layer.

An insulating layer 53 is disposed on the stacked body LMb, and an insulating layer 54 is disposed on the insulating layer 53. These insulating layers 53 and 54 are, for example, SiO₂ layers.

As illustrated in FIG. 2A, in the memory region MR, the plurality of pillars PL is disposed in the stacked bodies LMa and LMb. Each of the pillars PL penetrates the stacked bodies LMa and LMb and reaches the source line SL. The upper end portions of the pillars PL are disposed in the insulating layer 53. Each of the pillars PL has a cross-sectional shape along each layer of the stacked bodies LMa and LMb, such as a circular shape, an elliptical shape, or an oval shape.

In such a case, each of the pillars PL may have a bowing shape in which the diameter of the lower end portion, that is, the end portion in contact with the source line SL, is smaller than the upper end portion in the stacked body LMa, that is, the end portion located at the height of the interface between the stacked bodies LMa and LMb, and the maximum diameter is provided between the upper end portion and the lower end portion. Each of the pillars PL may have a bowing shape in which the diameter of the lower end portion in the stacked body LMb, that is, the end portion located at the height of the interface between the stacked bodies LMa and LMb, is smaller than the upper end portion, that is, the end portion located in the insulating layer 53, and the maximum diameter is provided between the upper end portion and the lower end portion.

Each of the pillars PL has a memory layer ME on the outer peripheral side of the pillar PL, a channel layer CN inside the memory layer ME, and a core layer CR filled inside the channel layer CN. The channel layer CN is in contact with the source line SL at the lower end of the pillar PL. The memory layer ME has a stacked structure in which a block insulating layer BK, a charge storage layer CT, and a tunnel insulating layer TN are stacked in this order from the outer peripheral side of the pillar PL. Further, each of the pillars PL has a cap layer CP having a diameter substantially equal to, for example, the outer shape of the channel layer CN, on the upper end portion side of the pillar PL.

The block insulating layer BK, the tunnel insulating layer TN, and the core layer CR are, for example, SiO₂ layers. The charge storage layer CT is, for example, a SiN layer. The channel layer CN and the cap layer CP include, for example, at least one of an amorphous silicon layer and a polysilicon layer.

On the upper surface of the cap layer CP, a plug CH is disposed which penetrates the insulating layers 53 and 54 and connects to, for example, the bit line not illustrated in the figure. FIG. 2A illustrates one cross section of the memory region MR, where the plug CH is depicted only on some of the pillars PL. However, in the cross section different in the X direction, the plug CH is also connected to the other pillar PL. Thus, the plugs CH are connected to all of the pillars PL that substantially contribute to the operation of the semiconductor memory device 1.

The above configuration allows a plurality of memory cells MC to be formed so as to be arranged in the height direction at the intersection of the pillar PL and the plurality of word lines WL. A selection gate STD is formed at the intersection of the pillar PL and the selection gate line SGD. When a selection gate line is disposed below the lowermost word line WL, the selection gate is also formed at the intersection of the selection gate line and the pillar PL.

Applying a predetermined voltage from the selection gate line SGD to the selection gate STD allows the selection gate STD to be turned on or off, and the memory cell MC formed on the pillar PL to which the selection gate STD belongs to be set to a selected state or an unselected state. Applying a predetermined voltage from the word line WL to the selected memory cell MC allows data to be written in the memory cell MC and data written in the memory cell MC to be read out.

As illustrated in FIGS. 2A and 2B, the contact LI penetrates the insulating layer 53 and the stacked bodies LMa and LMb and reaches the source line SL. In such a case, the contact LI may have a bowing shape in which the width of the bottom surface in the Y direction is smaller than the width of the upper surface in the Y direction and the maximum width is provided between the upper surface and the bottom surface. The contact LI extends along the X direction in the memory region MR and the through contact region TP, and reaches the stepped region SR (see FIG. 1A) at both end portions of the stacked bodies LMa and LMb in the X direction. Thus, the contact LI divides the stacked bodies LMa and LMb in the Y direction.

The contact LI has an insulating layer 56 disposed on its side wall and a conductive layer 21 filled inside the insulating layer 56. On the conductive layer 21 of the contact LI, a plug VO is disposed which penetrates the insulating layer 54 and connects to, for example, an upper layer wiring not illustrated in the figure. Thus, the contact LI functions as, for example, a source-line contact.

As illustrated in FIG. 2B, in the through contact region TP, an insulating region NR surrounded by the stacked bodies LMa and LMb is arranged as viewed from the stacking direction of each layer of the stacked bodies LMa and LMb. The insulating region NR includes a stacked body LMar disposed on the source line SL and a stacked body LMbr disposed on the stacked body LMar.

Both of the stacked bodies LMar and LMbr as the second stacked body have a configuration in which insulating layers NL as a plurality of second insulating layers are stacked via the insulating layer OL as the first insulating layer. The insulating layers NL in the stacked bodies LMar and LMbr have the number of stacked layers equal to the total number of stacked layers of the word lines WL and the selection gate lines SGD in the stacked bodies LMa and LMb, for example, and are disposed at the height position equal to the word lines WL and selection gate lines SGD.

The insulating layer NL is, for example, a SiN layer. The insulating layer OL is made of a material equal to the insulating layer OL of the stacked bodies LMa and LMb, and is, for example, a SiO₂ layer.

One or more contacts C4, for example, are disposed in the insulating region NR. The contact C4 penetrates the insulating layer 53 and the stacked bodies LMar and LMbr and reaches the insulating layer 50 covering the peripheral circuit CUA. The source line SL at the position where the contact C4 is disposed may be removed, and the contact C4 extends to the insulating layer 50 through a portion where the source line SL is removed, for example. In such a case, the contact C4 may have a bowing shape in which the diameter of the lower end portion is smaller than that of the upper end portion and the maximum diameter is provided between the upper end portion and the lower end portion.

The contact C4 has an insulating layer 57 disposed on the outer periphery of the contact C4, and a conductive layer 22 filled inside the insulating layer 57. The insulating layer 57 is, for example, a SiO₂ layer, and the conductive layer 22 is, for example, a tungsten layer. In the insulating layer 50, the conductive layer 22 of the contact C4 is connected to the peripheral circuit CUA (see FIG. 1A) via, for example, vias and wirings not illustrated in the figure. At the upper end portion of the conductive layer 22 of the contact C4, the plug VO is disposed which penetrates the insulating layer 54 and connects to, for example, an upper layer wiring not illustrated in the figure.

As described above, the contact C4 is disposed in the insulating region NR, and the word line WL, for example, is not disposed around the contact C4. Thus, the contact C4 and the word line WL can be suppressed from being electrically short-circuited, for example. Therefore, as described above, in the example of FIG. 2B, the contact C4 has the liner of the insulating layer 57, but the insulating layer 57 may be omitted if the contact C4 is sufficiently electrically insulated from other structures.

In the manufacturing process of the semiconductor memory device 1 to be described below, in order to secure the insulating region NR in which the stacked bodies LMar and LMbr without having, for example, the word line WL are disposed in the stacked bodies LMa and LMb, the plate-like portion BR described below is used.

On both sides in the Y direction of the insulating region NR, the plate-like portions BR are disposed between the stacked bodies LMa and LMb and the stacked bodies LMar and LMbr. In other words, one side surface in the Y direction of the plate-like portion BR faces the stacked bodies LMa and LMb, and the other side surface faces the stacked bodies LMar and LMbr. In such a case, the plate-like portion BR may have a bowing shape in which the width of the bottom surface in the Y direction is smaller than the width of the upper surface in the Y direction and the maximum width is provided between the upper surface and the bottom surface.

The plate-like portion BR has a configuration similar to, for example, that of the contact LI. In other words, the plate-like portion BR has the insulating layer 56 disposed on its side wall and the conductive layer 21 filled inside the insulating layer 56. However, the insulating layer 56 is also disposed on the bottom surface of the plate-like portion BR, and the conductive layer 21 is not in contact with the source line SL.

The insulating layer 56 as the third insulating layer is the same layer disposed on the side walls of the contact LI and the plate-like portion BR as described above, and is, for example, a SiO₂ layer. The conductive layer 21 as the third conductive layer is the same layer filled inside the contact LI and the plate-like portion BR as described above, and may include, for example, at least one of a tungsten layer and a polysilicon layer.

As described above, in the through contact region TP, the plate-like portions BR as the pair of first plate-like portions are disposed between the stacked bodies LMa and LMb and the stacked bodies LMar and LMbr, on both sides of the stacked bodies LMar and LMbr. The contact LI as the pair of second plate-like portions sandwiches the pair of plate-like portions BR from both sides in the Y direction at a position apart from the pair of plate-like portions BR.

The plurality of columnar portions HR is disposed in a region except the periphery of the contact C4 of the through contact region TP. At least a part of the columnar portion HR out of the plurality of columnar portions HR penetrates the stacked bodies LMa and LMb and reaches the source line SL. Some other columnar portions HR out of the plurality of columnar portions HR may penetrate the stacked bodies LMar and LMbr and reach the source line SL. The upper end portions of the columnar portions HR are disposed in the insulating layer 53. Each of the columnar portions HR has a cross-sectional shape along each layer of the stacked bodies LMa and LMb and the stacked bodies LMar and LMbr, such as a circular shape, an elliptical shape, or an oval shape.

In such a case, each of the columnar portions HR may have a bowing shape in which the diameter of the lower end portion in the stacked body LMa or the stacked body LMar, that is, the end portion in contact with the source line SL, is smaller than the upper end portion in the stacked body LMa or the stacked body LMar, and the maximum diameter is provided between the upper end portion and the lower end portion. Similarly, each of the columnar portions HR may have a bowing shape in which the diameter of the lower end portion in the stacked body LMb or the stacked body LMbr is smaller than the diameter of the upper end portion in the stacked body LMb or the stacked body LMbr, that is, the end portion located in the insulating layer 53, and the maximum diameter is provided between the upper end portion and the lower end portion.

The columnar portion HR is, for example, an insulating layer such as a SiO₂ layer or the same constituent layer as the pillar PL, and does not contribute to the function of the semiconductor memory device 1. As will be described below, when the stacked bodies LMa and LMb are formed from the stacked body in which the sacrificial layer and the insulating layer are stacked, the columnar portion HR serves to support these structures.

A more detailed configuration of the plate-like portion BR and the contact LI will now be described.

As illustrated in FIG. 2C, the side wall facing the stacked bodies LMa and LMb and the side wall facing the stacked bodies LMar and LMbr out of the side walls on both sides in the Y direction of the plate-like portion BR have different configurations.

The side wall of the plate-like portion BR as second side wall facing the stacked bodies LMar and LMbr has a block layer 62, an insulating layer 56, and a barrier metal layer 24 in order from the side close to the outside of the plate-like portion BR, that is, from the side of the stacked bodies LMar and LMbr. The block layer 62, the insulating layer 56, and the barrier metal layer 24 are disposed over the entire height position of the insulating layer 53 and the insulating layers OL and NL of the stacked bodies LMar and LMbr.

The block layer 62 as the metal element-containing layer is, for example, a metal oxide layer such as an Al₂O₃ layer, a HfO₂ layer, or a ZrO₂ layer. The block layer 62 is in contact with the end surface of the insulating layer 53 facing the plate-like portion BR and the end surfaces of the insulating layers OL and NL of the stacked bodies LMa and LMb facing the plate-like portion BR.

The barrier metal layer 24 is, for example, a TiN layer, and is disposed in contact with the conductive layer 21 such as a tungsten layer or a molybdenum layer to suppress diffusion of metal atoms constituting the conductive layer 21 into other adjacent layers. Therefore, the barrier metal layer 24 may be formed of at least one of, for example, a Ti layer, a TiN layer, a Ta layer, and a TaN layer. When the conductive layer 21 to be filled in the plate-like portion BR is, for example, a polysilicon layer, the barrier metal layer 24 may not be disposed on the side wall of the plate-like portion BR.

In other words, on the stacked bodies LMar and LMbr side, the block layer 62 is interposed between the insulating layer 56 described above, disposed on the side wall of the plate-like portion BR and the end surfaces of the insulating layers OL and NL of the stacked bodies LMar and LMbr. On the stacked bodies LMar and LMbr sides, the barrier metal layer 24, for example, is interposed between the insulating layer 56 on the side wall of the plate-like portion BR and the conductive layer 21.

The side wall of the plate-like portion BR as first side wall facing the stacked bodies LMa, LMb has the block layer 62 that covers the end surface of the insulating layer 53 facing the plate-like portion BR and the end surfaces of the insulating layers OL of the stacked bodies LMa and LMb facing the plate-like portion BR.

The block layer 62 extends in a direction further away from the plate-like portion BR from the end surface of the insulating layer OL, and covers both surfaces in the stacking direction of the insulating layer OL, that is, a surface facing the word line WL or the selection gate line SGD. A barrier metal layer 23 is interposed between the block layer 62 on the surface of the insulating layer OL, and the word line WL and the selection gate line SGD. In other words, the block layer 62 and the barrier metal layer 23, in order from the insulating layer OL side, are interposed between the word line WL and the insulating layer OL, and between the selection gate line SGD and the insulating layer OL. The block layer 62 and the barrier metal layer 23 are not disposed on the end surface of the word line WL facing the plate-like portion BR.

The barrier metal layer 23 as the second conductive layer is, for example, a TiN layer, and as described above, suppresses diffusion of metal atoms constituting a predetermined conductive layer into other adjacent layers. Therefore, the barrier metal layer 23 may be formed of at least one of, for example, a Ti layer, a TiN layer, a Ta layer, and a TaN layer.

The side wall of the plate-like portion BR facing the stacked bodies LMa and LMb has an insulating layer 56 disposed over the entire height position of the insulating layer 53 and the insulating layers OL, word lines WL and selection gate lines SGD of the stacked bodies LMa and LMb. The block layer 62 is interposed between the insulating layer 56 and the end surface of the insulating layer 53 facing the plate-like portion BR and the end surfaces of the insulating layer OL of the stacked bodies LMa and LMb facing the plate-like portion BR. The insulating layer 56 is in direct contact with the end surfaces of the word line WL and the selection gate line SGD of the stacked bodies LMa and LMb facing the plate-like portions BR.

The end surfaces of the word lines WL and the selection gate lines SGD of the stacked bodies LMa and LMb facing the plate-like portion BR may be located at positions retreated from the plate-like portion BR than the end surfaces of the insulating layers OL covered with the block layer 62. Thus, at the height positions of the word lines WL and the selection gate lines SGD, the insulating layer 56 of the plate-like portion BR may protrude toward the word lines WL and the selection gate lines SGD.

The side wall of the plate-like portion BR facing the stacked bodies LMa and LMb has a barrier metal layer 24 disposed over the entire height position of the insulating layer 53 and the insulating layers OL, word lines WL and selection gate lines SGD of the stacked bodies LMa and LMb. The barrier metal layer 24 is disposed further inside the block layer 62 and the insulating layer 56.

In other words, on the stacked bodies LMa and LMb sides, the insulating layer 56 described above, disposed on the side wall of the plate-like portion BR is in direct contact with the end surfaces of the word line WL and the selection gate line SGD of the stacked bodies LMa and LMb without interposing the block layers 62. Also on the stacked bodies LMa and LMb sides, the barrier metal layer 24, for example, is interposed between the insulating layer 56 on the side wall of the plate-like portion BR and the conductive layer 21. However, as described above, when the conductive layer 21 to be filled in the plate-like portion BR is, for example, a polysilicon layer, the barrier metal layer 24 may not be disposed on the side wall of the plate-like portion BR.

On the other hand, the side walls on both sides in the Y direction of the contact LI have the same configuration each other.

The side wall of the contact LI has a block layer 62 covering the end surface of the insulating layer 53 facing the contact LI, and the end surfaces of the insulating layers OL of the stacked bodies LMa and LMb facing the contact LI. The block layer 62 extends in a direction further away from the contact LI from the end surface of the insulating layer OL, and covers both surfaces in the stacking direction of the insulating layer OL, that is, a surface facing the word line WL or the selection gate line SGD. Further, the barrier metal layer 23 is interposed between the block layer 62, and the word line WL and the selection gate line SGD. The block layer 62 and the barrier metal layer 23 are not disposed on the end surface of the word line WL facing the contact LI.

The side wall of the contact LI has an insulating layer 56 disposed over the entire height position of the insulating layer 53 and the insulating layers OL, word lines WL and selection gate lines SGD of the stacked bodies LMa and LMb. The block layer 62 is interposed between the insulating layer 56 and the end surface of the insulating layer 53 facing the contact LI and the end surfaces of the insulating layer OL of the stacked bodies LMa and LMb facing the contact LI. The insulating layer 56 is in direct contact with the end surfaces of the word line WL and the selection gate line SGD of the stacked bodies LMa and LMb facing the contact LI.

The end surfaces of the word lines WL and the selection gate lines SGD of the stacked bodies LMa and LMb facing the contact LI may be located at positions retreated from the contact LI than the end surfaces of the insulating layers OL covered with the block layer 62. Thus, at the height positions of the word lines WL and the selection gate lines SGD, the insulating layer 56 of the contact LI may protrude toward the word lines WL and the selection gate lines SGD.

The side wall of the contact LI has a barrier metal layer 24 disposed over the entire height position of the insulating layer 53 and the insulating layers OL, word lines WL and selection gate lines SGD of the stacked bodies LMa and LMb. The barrier metal layer 24 is disposed further inside the block layer 62 and the insulating layer 56.

In other words, the barrier metal layer 24, for example, is interposed between the insulating layer 56 described above, disposed on the side wall of the contact LI and the conductive layer 21. However, as in the case of the plate-like portion BR described above, when the conductive layer 21 to be filled in the contact LI is, for example, a polysilicon layer, the barrier metal layer 24 may not be disposed on the side wall of the contact LI. The block layer 62 is interposed between the insulating layer 56 on the side wall of the contact LI and the end surfaces of the insulating layers OL of the stacked bodies LMa and LMb. The insulating layer 56 on the side wall of the contact LI is in direct contact with the end surfaces of the word line WL and the selection gate line SGD of the stacked bodies LMa and LMb without interposing the block layer 62.

The block layer 62, the insulating layer 56, the barrier metal layer 24, and the conductive layer 21 of the contact LI are the same layers formed in parallel with the block layer 62, the insulating layer 56, the barrier metal layer 24, and the conductive layer 21 of the plate-like portion BR, respectively, as will be described below.

As will be described below, the barrier metal layer 23 disposed in contact with the word line WL is formed separately from the barrier metal layer 24 disposed inside the contact LI and the plate-like portion BR. Therefore, the barrier metal layers 23 and 24 may be made of the same material or different materials.

As described above, the side walls on both sides in the Y direction of the contact LI have a layer structure different from the side wall of the plate-like portion BR facing the stacked bodies LMar and LMbr. On the other hand, the side walls on both sides in the Y direction of the contact LI have the same layer structure as the side wall of the plate-like portion BR facing the stacked bodies LMa and LMb. In other words, the side walls on both sides in the Y direction of the contact LI and the side wall of the plate-like portion BR facing the stacked bodies LMa and LMb have the same layer structure as each other served as the first layer structure at each height position of the plurality of word lines WL. The side walls on both sides in the Y direction of the contact LI and the side wall of the plate-like portion BR facing the stacked bodies LMa and LMb have the same layer structure as each other served as the second layer structure at each height position of the plurality of insulating layers OL.

The configuration around the columnar portion HR will be further described.

The side surface of the columnar portion HR is in direct contact with the end surface of the insulating layer 53 facing the columnar portion HR and the end surfaces of the insulating layer OL of the stacked bodies LMa and LMb facing the columnar portion HR. The block layer 62 and the barrier metal layer 23 are interposed between the side surfaces of the columnar portions HR and the end surfaces of the word line WL and the selection gate line SGD of the stacked bodies LMa and LMb facing the columnar portions HR. The block layer 62 and the barrier metal layer 23 are disposed in this order from the columnar portion HR side.

More specifically, the block layer 62 covering both surfaces in the stacking direction of the insulating layer OL described above also covers the end surfaces of the word line WL and the selection gate line SGD facing the columnar portions HR. On both surfaces in the stacking direction of the insulating layer OL, the barrier metal layers 23 interposed between the block layer 62 and the word line WL and between the block layer 62 and the selection gate line SGD further extend to the end surfaces of the word line WL and the selection gate line SGD facing the columnar portion HR, and are interposed between the block layer 62 and the word line WL and between the block layer 62 and the selection gate line SGD.

Although not illustrated in the figure, the same configuration as that of the columnar portion HR can be seen around the pillar PL.

In other words, the block layer 62 covering both surfaces in the stacking direction of the insulating layer OL also covers the end surfaces of the word line WL and the selection gate line SGD facing the pillar PL. On both surfaces in the stacking direction of the insulating layer OL, the barrier metal layers 23 interposed between the block layer 62 and the word line WL and between the block layer 62 and the selection gate line SGD further extend to the end surfaces of the word line WL and the selection gate line SGD facing the pillar PL, and are interposed between the block layer 62 and the word line WL and between the block layer 62 and the selection gate line SGD.

Thus, the side surface of the pillar PL is in direct contact with the end surface of the insulating layer 53 facing the pillar PL and the end surfaces of the insulating layer OL of the stacked bodies LMa and LMb facing the pillar PL. The block layer 62 and the barrier metal layer 23 are interposed between the side surfaces of the pillars PL and the end surfaces of the word line WL and the selection gate line SGD of the stacked bodies LMa and LMb facing the pillars PL.

Thus, in the vicinity of the columnar portion HR and the pillar PL, the block layer 62, the barrier metal layer 23, and the word line WL surround the columnar portion HR and the pillar PL, respectively, in this order from the columnar portion HR side and the pillar PL side, for example, concentrically, when viewed from the stacking direction of each layer of the stacked bodies LMa and LMb.

(Method of Manufacturing Semiconductor Memory Device)

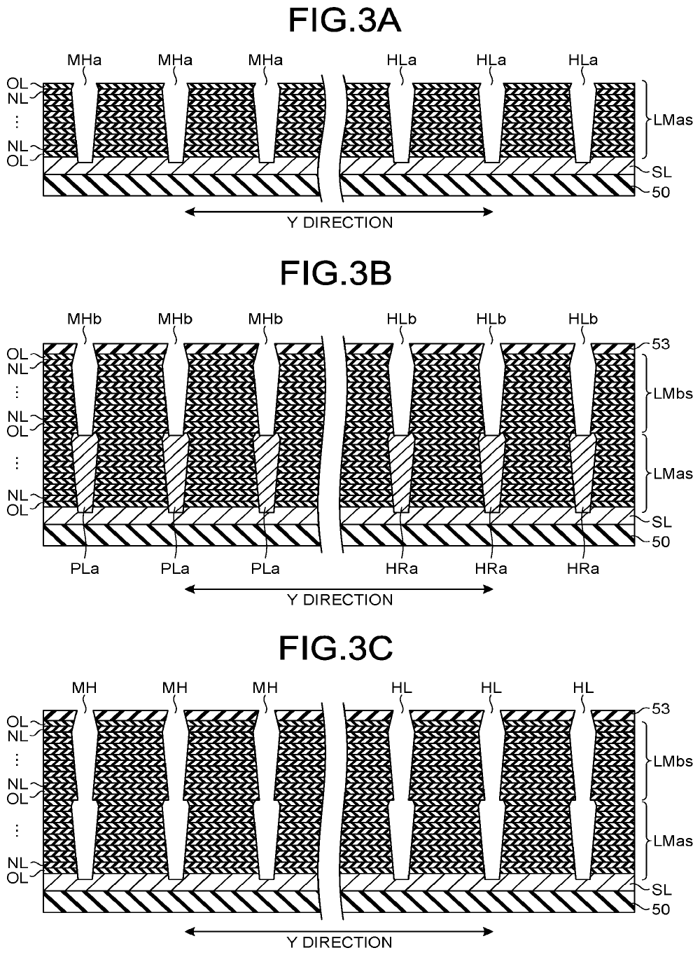

A method of manufacturing the semiconductor memory device 1 according to the first embodiment will then be described with reference to FIGS. 3A to 8C. FIGS. 3A to 8C are cross-sectional views along the Y direction illustrating an example of the procedure of the method of manufacturing the semiconductor memory device 1 according to the first embodiment. In FIGS. 3A to 8C, the peripheral circuit CUA is omitted.

FIGS. 3A to 5C illustrate an example of a method of forming the pillars PL and the columnar portions HR of the semiconductor memory device 1 according to the first embodiment. In FIGS. 3A to 5C, the left sides of the figures illustrate how the pillar PL is formed, and the right sides of the figures illustrate how the columnar portion HR is formed. It is assumed that the peripheral circuit CUA, the insulating layer 50 covering the peripheral circuit CUA, and the source line SL on the insulating layer 50 have been formed prior to the processes illustrated in FIGS. 3A to 3C.

As illustrated in FIG. 3A, a stacked body LMas in which the plurality of insulating layers NL as second insulating layers are stacked via the insulating layer OL as the first insulating layer is formed on the source line SL. The insulating layer NL is a sacrificial layer that is replaced by a conductive layer, such as a tungsten layer or a molybdenum layer, in a later process to become a word line WL. A portion of the insulating layer NL remains as a portion of the stacked body LMar without being replaced by the conductive layer.

A plurality of memory holes MHa and a plurality of holes HLa are formed which penetrate the stacked body LMas to reach the source line SL.

As illustrated in FIG. 3B, a sacrificial layer such as an amorphous silicon layer is filled in each of the memory holes MHa to form a plurality of pillars PLa. A sacrificial layer such as an amorphous silicon layer is filled in each of the holes HLa to form a plurality of columnar portions HRa.

A stacked body LMbs in which the plurality of insulating layers NL as second insulating layers are stacked via the insulating layer OL as the first insulating layer is formed on the stacked body LMas. The insulating layer NL is a sacrificial layer that is replaced by a conductive layer, such as a tungsten layer or a molybdenum layer, in a later process to become a word line WL or a selection gate line SGD. A portion of the insulating layer NL remains as a portion of the stacked body LMbr without being replaced by the conductive layer.

An insulating layer 53 covering the upper surface of the stacked body LMbs is formed. Then, a plurality of memory holes MHb and a plurality of holes HLb are formed penetrating the insulating layer 53 and the stacked body LMbs to reach the stacked body LMas. In such a case, each of the plurality of memory holes MHb is connected to the corresponding pillar PLa. Each of the plurality of holes HLb is connected to the corresponding columnar portion HRa.

As illustrated in FIG. 3C, a plurality of memory holes MH penetrating the insulating layer 53 and the stacked bodies LMas and LMbs and reaching the source line SL is formed which removes the sacrificial layer in the lower memory hole MHa via the plurality of memory holes MHb. A plurality of holes HL penetrating the insulating layer 53 and the stacked bodies LMas and LMbs and reaching the source line SL is formed which removes the sacrificial layer in the lower hole HLa via the plurality of holes HLb.

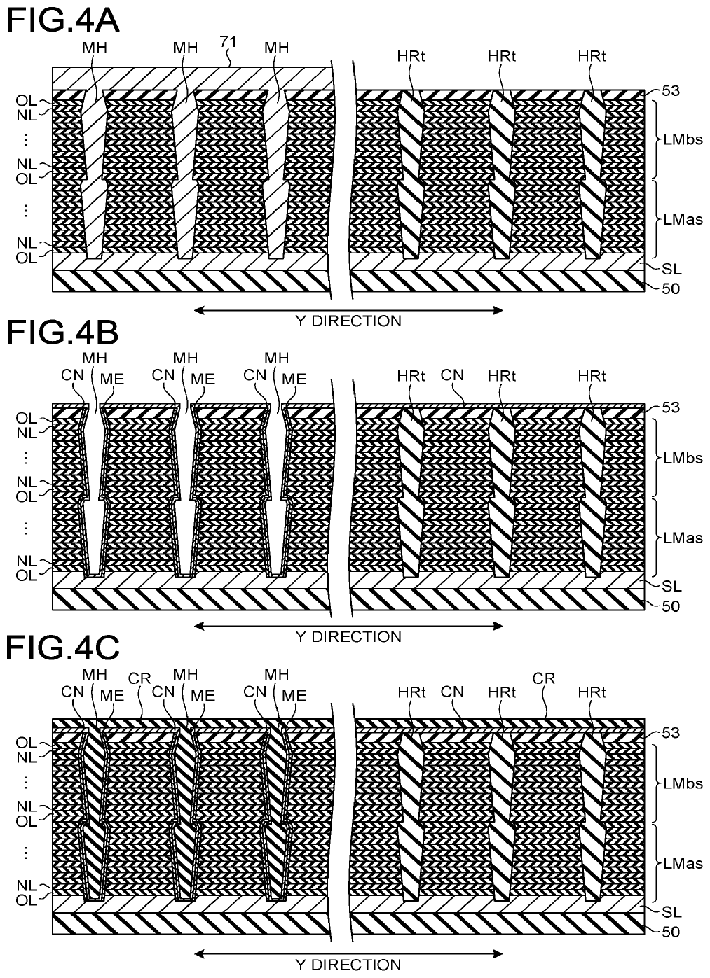

As illustrated in FIG. 4A, an insulating layer such as a SiO₂ layer is filled in the plurality of holes HL with the plurality of memory holes MH covered with a resist layer 71. Thus, a plurality of columnar portions HRt penetrating the insulating layer 53 and the stacked bodies LMas and LMbs and reaching the source line SL is formed.

As illustrated in FIG. 4B, after the resist layer 71 covering the plurality of memory holes MH is removed, the memory layer ME is formed on the side walls and bottom surfaces of each of the memory holes MH and on the upper surface of the insulating layer 53. In other words, the block insulating layer BK, the charge storage layer CT, and the tunnel insulating layer TN are formed in this order from the outer peripheral side of the memory hole MH. The memory layer ME formed on the bottom surface of the memory hole MH may be removed. In this case, the memory layer ME on the upper surface of the insulating layer 53 is also removed.

The channel layer CN is formed inside the memory layer ME of the memory hole MH. When the memory layer ME on the bottom surface of the memory hole MH is removed, the channel layer CN is also formed on the bottom surface of the memory hole MH. Further, the channel layer CN is also formed on the upper surface of the insulating layer 53 in which the memory hole MH is formed, the upper surface of the insulating layer 53 in which the columnar portion HRt is formed, and the upper surface of the columnar portion HRt.

As illustrated in FIG. 4C, the inside of the channel layer CN of the plurality of memory holes MH is filled with the core layer CR. The core layer CR is also formed, interposing the channel layer CN, on the upper surface of the insulating layer 53 in which the memory hole MH is formed, the upper surface of the insulating layer 53 in which the columnar portion HRt is formed, and the upper surface of the columnar portion HRt.

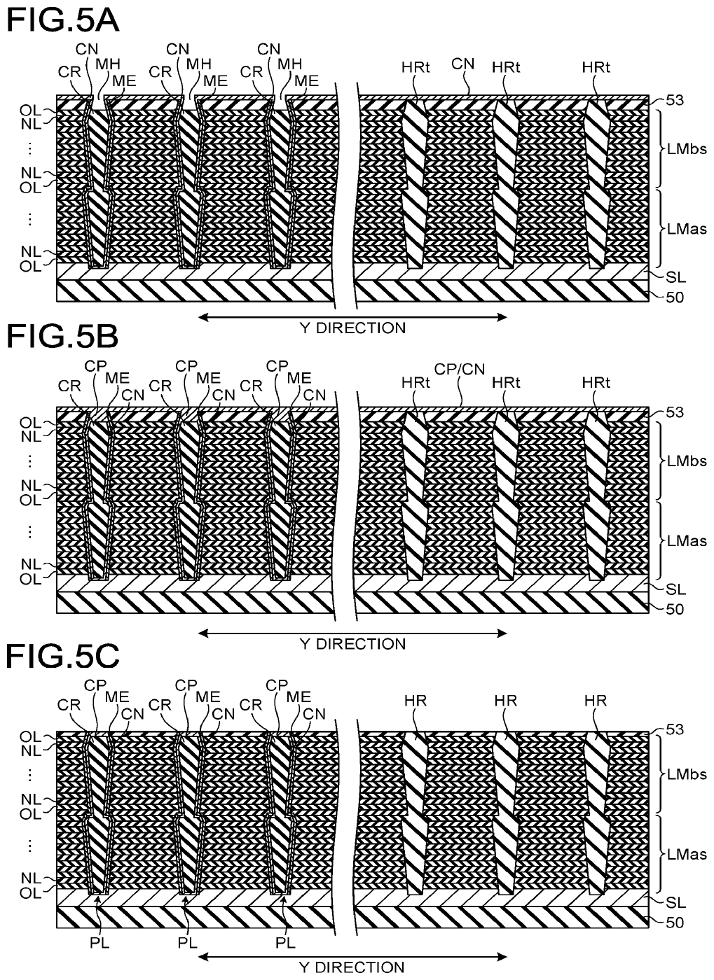

As illustrated in FIG. 5A, the core layer CR on the upper surface of the insulating layer 53 in which the memory hole MH is formed, the upper surface of the insulating layer 53 in which the columnar portion HRt is formed, and the upper surface of the columnar portion HRt are removed by etch back. Thus, the upper end portion of the core layer CR filled in the memory hole MH is removed. On the other hand, at the columnar portion HRt, the channel layer CN serves as an etch-stopper layer, and the upper end portion of the columnar portion HRt is not removed.

As illustrated in FIG. 5B, the upper end portion of the memory hole MH from which the core layer CR has been removed is filled with the cap layer CP. In such a case, the cap layer CP may also be formed on the upper surface of the insulating layer 53 in which the memory hole MH is formed, the upper surface of the insulating layer 53 in which the columnar portion HRt is formed, and the upper surface of the columnar portion HRt.

As illustrated in FIG. 5C, the cap layers CP and the channel layer CN on the upper surface of the insulating layer 53 in which the memory hole MH is formed, the upper surface of the insulating layer 53 in which the columnar portion HRt is formed, and the upper surface of the columnar portion HRt, and the memory layer ME if the memory layer ME is left, are further removed by etch back. Further, the etch back is also continued to the upper surface of the insulating layer 53 in which the cap layer CP and the channel layer CN are removed to expose the memory hole MH, and to the upper surface of the insulating layer 53 in which the columnar portion HRt is exposed.

Thus, a plurality of pillars PL having the cap layer CP at its upper end portion is formed in which the cap layer CP is exposed from the upper surface of the thinned insulating layer 53. A plurality of columnar portions HR is formed in which the upper end portion is exposed from the upper surface of the thinned insulating layer 53.

The insulating layer 53 is subsequently piled up so as to cover the upper surface of the cap layer CP and the upper surface of the columnar portion HR.

At any timing in the processes of FIGS. 3A to 5C, the stepped regions SR are formed at both end portions in the X direction of the stacked bodies LMas and LMbs.

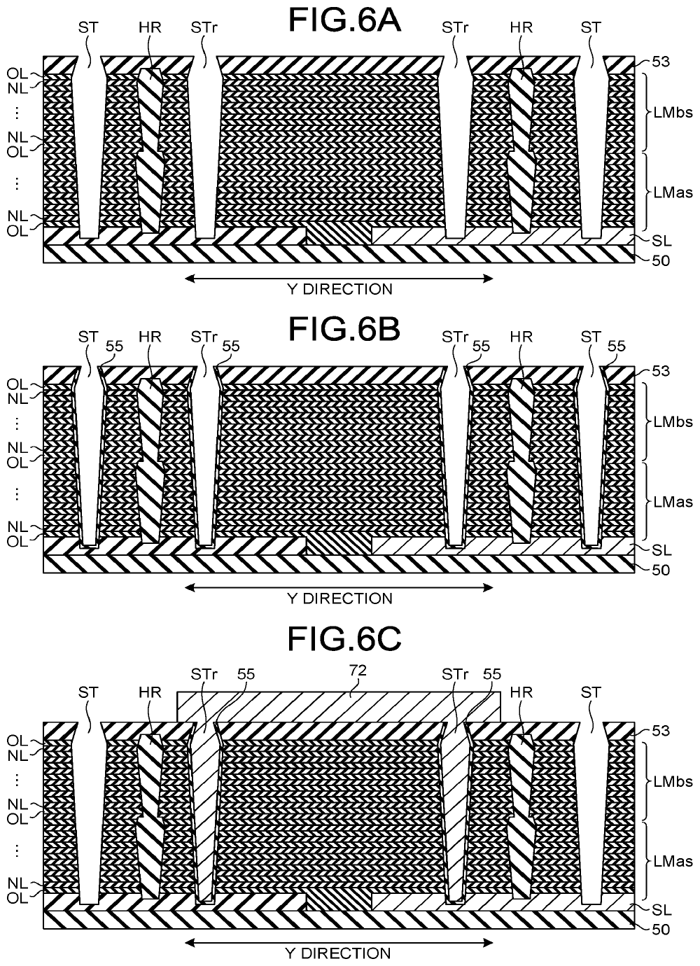

FIGS. 6A to 8C illustrate an example of a method of forming the contact LI and the plate-like portion BR of the semiconductor memory device 1 according to the first embodiment. The cross-sectional views illustrated in FIGS. 6A to 8C correspond to the regions illustrated in the cross-sectional views of FIG. 2B described above.

As illustrated in FIG. 6A, slits ST and STr are formed which penetrate the insulating layer 53 and the stacked bodies LMas and LMbs to reach the source line SL. The slit ST is formed at a position where the contact LI is disposed, while the slit STr is formed at a position where the plate-like portion BR is disposed.

As illustrated in FIG. 6B, insulating layers 55 are formed on the side walls and bottom surfaces of the slits ST and STr. As with the insulating layer constituting the columnar portion HR, the insulating layer 55 is, for example, a SiO₂ layer. However, the insulating layer 55 is preferably a dense layer similar to the block insulating layer BK formed in the memory hole MH. Thus, the dense insulating layer 55 can be obtained, for example, by adjusting the conditions for forming the insulating layer 55.

As illustrated in FIG. 6C, the insulating layer 55 on the side wall and the bottom surface of the slit ST is removed with the slit STr covered with a resist layer 72.

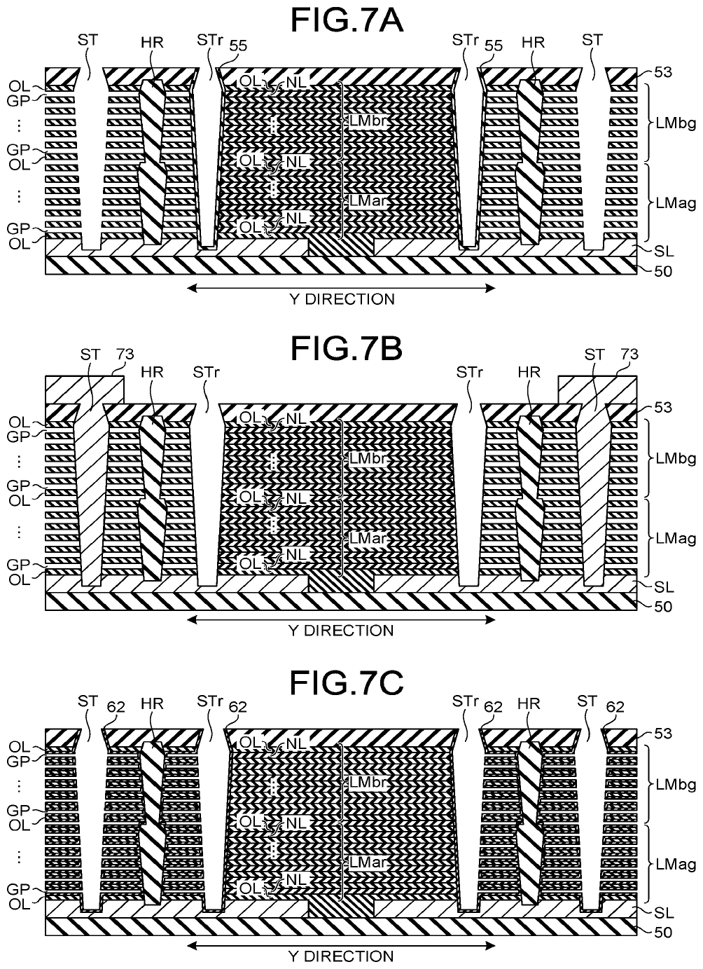

As illustrated in FIG. 7A, after the resist layer 72 covering the slit STr is removed, a thermal phosphoric acid solution, for example, is made to flow in from the slit ST to remove the insulating layers NL of the stacked bodies LMas and LMbs. Thus, the stacked bodies LMas and LMbs excluding the region sandwiched by the slits STr become the stacked bodies LMag and LMbg in which a plurality of gaps GP from which the insulating layer NL is removed is disposed via the insulating layer OL.

The stacked bodies LMag and LMbg including a plurality of gaps GP are fragile structures, and thus deformation and collapse may occur. In the through contact region TP, the columnar portion HR extending from the insulating layer 53 to the source line SL supports the fragile stacked bodies LMag and LMbg. In the memory region MR not illustrated in the figure, the pillar PL extending from the insulating layer 53 to the source line SL supports the fragile stacked bodies LMag and LMbg. Those structures suppress the stacked bodies LMag and LMbg from being deformed or collapsed.

On the other hand, the slit STr has a dense insulating layer 55 on its side wall. Therefore, the flow of the thermal phosphoric acid solution from the slit ST to the inside in the Y direction of the stacked bodies LMas and LMbs is stopped by the slit STr. The treatment with the thermal phosphoric acid solution is completed before the thermal phosphoric acid solution flowing in from the slit ST flows from the X direction side and flows into the region sandwiched by the pair of slits STr.

Thus, in the region sandwiched by the pair of slits STr, the insulating layers NL of the stacked bodies LMas and LMbs are maintained without being removed, and the stacked bodies LMar and LMbr are formed in the region sandwiched by the pair of slits STr.

As illustrated in FIG. 7B, the insulating layer 55 on the side wall and the bottom surface of the slit STr is removed with the slit ST covered with a resist layer 73.

In such a case, the upper and lower surfaces of the insulating layer OL of the stacked bodies LMag and LMbg from which the insulating layer NL is removed are exposed. Therefore, it is noted so as that the insulating layer OL are not eroded in the layer thickness direction to be less than a desired layer thickness at this point.

In anticipation that even the insulating layer OL will be eroded when the insulating layer 55 is removed, the insulating layer OL may be formed thicker than a desired layer thickness in advance so that the insulating layer OL having a desired layer thickness can be obtained after the insulating layer 55 is removed.

When the insulating layer 55 is removed, the end surface of the insulating layer OL facing the slit STr may also be retreated from the slit STr. However, it is considered that the retreating of the end surface of the insulating layer OL hardly affects the function of the semiconductor memory device 1.

The removal of the insulating layer 55 from the side wall of the slit STr allows the slit STr to be communicated with the gaps GP of the stacked bodies LMag and LMbg.

As illustrated in FIG. 7C, after the resist layer 73 covering the slit ST is removed, a material gas of the block layer 62, such as an Al₂O₃ layer, is made to flow in from the slits ST and STr to form the block layer 62 on the upper and lower surfaces of the insulating layers OL of the stacked bodies LMag and LMbg.

In such a case, the block layer 62 is also formed on the side wall of the slit STr on the stacked bodies LMar and LMbr sides over the entire height position of the insulating layer 53 and the insulating layers NL and OL of the stacked bodies LMar and LMbr. The block layer 62 is formed on the side wall of the slit STr on the stacked bodies LMag and LMbg sides, that is, on the end surface of the insulating layer 53 and the end surface of the insulating layer OL of the stacked bodies LMag and LMbg. Similarly, the block layer 62 is formed on the side walls on both sides in the Y direction of the slit ST, that is, on the end surface of the insulating layer 53 and the end surface of the insulating layer OL of the stacked bodies LMag and LMbg. The block layer 62 is also formed in portions of the slits ST and STr in contact with the source line SL, including the bottom surfaces of the slits ST and STr. Further, the block layer 62 is formed on the side surface at the height position of the gap GP of the stacked bodies LMag and LMbg out of the side surfaces of the columnar portions HR.

A material gas of the barrier metal layer 23, such as a TiN layer, is made to flow in from the slits ST and STr to form the barrier metal layer 23 (see FIG. 2C) on the upper and lower surfaces of the insulating layers OL of the stacked bodies LMag and LMbg via the block layers 62.

In such a case, the barrier metal layer 23 is further formed on the block layers 62 formed on the side walls in the Y direction and the bottom surfaces of the slits ST and STr. The barrier metal layer 23 is formed on the side surface at the height position of the gap GP of the stacked bodies LMag and LMbg via the block layer 62, out of the side surfaces of the columnar portions HR.

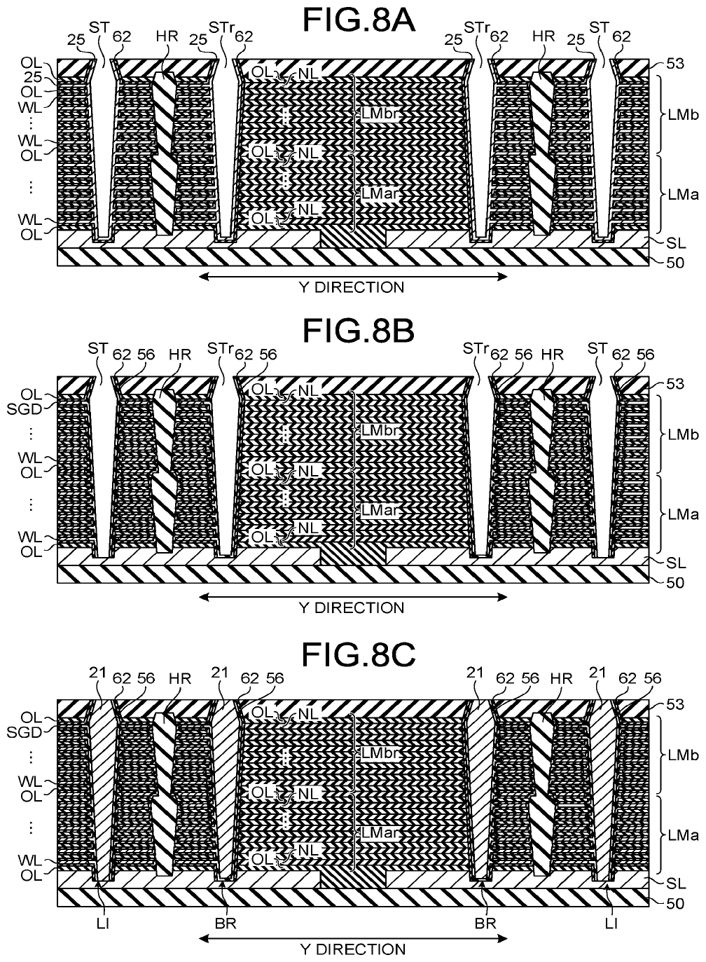

As illustrated in FIG. 8A, a material gas of the conductive layer 25 such as a tungsten layer or a molybdenum layer is made to flow in from the slits ST and STr to fill the gap GP of the stacked bodies LMag and LMbg with the conductive layer 25. Thus, the stacked bodies LMa and LMb are formed in which a plurality of word lines WL is stacked via the insulating layer OL.

In such a case, the conductive layer 25 is also formed on the side walls of the slits ST and STr. The peripheral configuration of the columnar portion HR described above with reference to FIG. 2C is formed at this point.

In the figure, the conductive layer 25 is to be formed at the height position of the uppermost gap GP of the stacked body LMb. The conductive layer 25 is partitioned into the selection gate line SGD separated in the Y direction by the separation layer SHE formed in a later process. However, the formation of the separation layer SHE can be performed in any timing out of various timings, and the separation layer SHE may have already been formed, for example, before the step illustrated in FIG. 8A.

The process for replacing the insulating layer NL with the word line WL, which is illustrated in FIGS. 7A to 8A, is also referred to as a replacement process, for example.

As illustrated in FIG. 8B, the conductive layer 25 and the barrier metal layer 23 (not illustrated) in the slits ST and STr are removed. In such a case, the end surfaces of the word line WL and the uppermost conductive layer 25 of the stacked bodies LMa and LMb in contact with the side walls of the slits ST and STr may be retreated.

After the block layers 62 on the bottom surfaces of the slits ST and STr are removed, the insulating layers 56 are formed on the side walls and bottom surfaces of the slits ST and STr. If the end surfaces of the word line WL and the uppermost conductive layer 25 of the stacked bodies LMa and LMb are retreated when removing the conductive layers 25 and the barrier metal layers 23 in the slits ST and STr, the insulating layers 56 on the side walls of the slits ST and STr protrude toward the word line WL side and the uppermost conductive layer 25 side and come in contact with these end surfaces.

Further, the insulating layer 56 is removed from the bottom surface of the slit ST. Instead of the above timing, the block layer 62 may be removed from the bottom surface of the slit ST in one step at this point. The insulating layer 56 and the block layer 62 may be left on the bottom surface of the slit STr.

The barrier metal layer 24 (see FIG. 2C), for example, is formed on the side walls and the bottom surfaces of the slits ST and STr. As described above, when the slits ST and STr are subsequently filled with the conductive layer 21 such as a polysilicon layer, the barrier metal layer 24 may not be formed.

As illustrated in FIG. 8C, the slits ST and STr are filled with the conductive layer 21 such as a tungsten layer or a polysilicon layer. Thus, the contact LI and the plate-like portion BR are formed which have the configurations described above with reference to FIG. 2C.

After this, a groove is subsequently provided which penetrates one or more conductive layers 25 including the uppermost conductive layer 25 of the stacked body LMb, and an insulating layer is filled in the groove to form the separation layer SHE. Thus, the conductive layer 25 through which the separation layer SHE penetrates is partitioned into the selection gate line SGD. However, as described above, the formation timing of the separation layer SHE is not limited to this point.

A through-hole is formed which penetrates the insulating layer 53 and the stacked bodies LMar and LMbr to reach the insulating layer 50 below the source line SL. The insulating layer 57 is formed on the side wall of the through-hole as necessary, and the inside of the insulating layer 57 is filled with the conductive layer 22. Thus, the contact C4 is formed. A plurality of contacts CC (see FIG. 1A) connected to each of the word lines WL and the selection gate lines SGD is formed in the stepped region SR.

The insulating layer 54 covering the insulating layer 53 on the stacked body LMb is formed. A through-hole is provided which penetrates the insulating layers 53 and 54 to reach the cap layer CP at the upper end portion of the pillar PL, and a conductive layer is filled in the through-hole to form the plug CH connected to the cap layer CP of the pillar PL. A through-hole is provided which penetrates the insulating layer 54 to reach the upper surfaces of the contacts LI, C4 and CC, and a conductive layer is filled in the through-hole to form the plug VO connected to the contacts LI, C4, and CC. Further, an upper layer wiring of the plugs CH and VO is formed, for example.

Thus, the semiconductor memory device 1 of the first embodiment is manufactured.

The semiconductor memory device 1 is not limited to the above example, and may employ a configuration in which the channel layer CN is connected to the source line SL at a side surface near the lower end portion of the pillar PL, for example.

In the manufacturing process of a semiconductor memory device such as a three-dimensional nonvolatile memory, a replacement process may be performed in which, while a sacrificial layer is left in some regions of a stacked body formed of a sacrificial layer such as a SiN layer and an insulating layer such as a SiO₂ layer, a sacrificial layer in other regions is replaced with a conductive layer. Thus, an insulating region having no conductive layer can be formed in the stacked body including the conductive layer.

In this case, for example, a slit having an insulating layer serving as a barrier for the replacement process on its side wall is formed so as to be close to both sides in the Y direction of some region where, for example, the sacrificial layer is left. A slit having no insulating layer on its side wall is formed at a position apart from these slits in the Y direction. In the replacement process, the sacrificial layer is removed through a slit having no insulating layer, and a conductive material is filled in the gap formed thereby to form a conductive layer.

The slit having an insulating layer on its side wall has a configuration in which an insulating layer used as a barrier for the replacement process is interposed between a block layer formed on the replaced stacked body side and a block layer formed inside the slit, by subsequent processes.

However, some issues may arise in the replacement process as described above. The material gas of the conductive layer flows from the vicinity of the slit having no insulating layer to the vicinity of the slit having an insulating layer over a predetermined time. Therefore, in a predetermined period of the replacement process, the filling density of the conductive material to the gap of the stacked body is high in the vicinity of the slit having no insulating layer and low in the vicinity of the slit having an insulating layer. Thus, tensile stress is generated from a region where the conductive material has a low density to a region where the conductive material has a high density, and the columnar portion supporting the stacked body and the stacked body itself may incline toward the high density region.

Therefore, it is also considered to fill the inside of the slit having an insulating layer with, for example, an insulating layer, before removing the sacrificial layer and to strengthen the connection of the stacked body on both sides in the Y direction of the slit, thereby suppressing the inclination of, for example, the columnar portion and the stacked body. However, in this case, cracks may occur, for example, in the insulating layer filled in the slit.

The method of manufacturing the semiconductor memory device 1 of the first embodiment is to remove the insulating layer 55 on the side wall of the slit STr after the insulating layer NL is removed and before the conductive layer 25 is filled. Thus, the conductive layer 25 can be filled in the gap GP of the stacked bodies LMag and LMbg from both the slits ST and STr. Therefore, the difference in the filling density of the conductive layer 25 between the vicinity of the slit ST and the vicinity of the slit STr can be reduced, and the inclination of, for example, the columnar portion HR and the stacked bodies LMag and LMbg can be suppressed.

The method of manufacturing the semiconductor memory device 1 of the first embodiment is to remove the insulating layer 55 on the side wall of the slit STr with the slit ST covered with the resist layer 73. Thus, the insulating layers OL of the stacked bodies LMag and LMbg can be suppressed from being eroded in the layer thickness direction from the slit ST side, for example, having no insulating layer 55.

The method of manufacturing the semiconductor memory device 1 of the first embodiment may form the layer thickness of the insulating layer OL thicker than a desired layer thickness in advance when the stacked bodies LMas and LMbs are formed, for example. Thus, even if the insulating layer OL is eroded in the layer thickness direction when the insulating layer 55 on the side wall of the slit STr is removed, the insulating layer OL after removal of the insulating layer 55 can be maintained at a desired layer thickness.

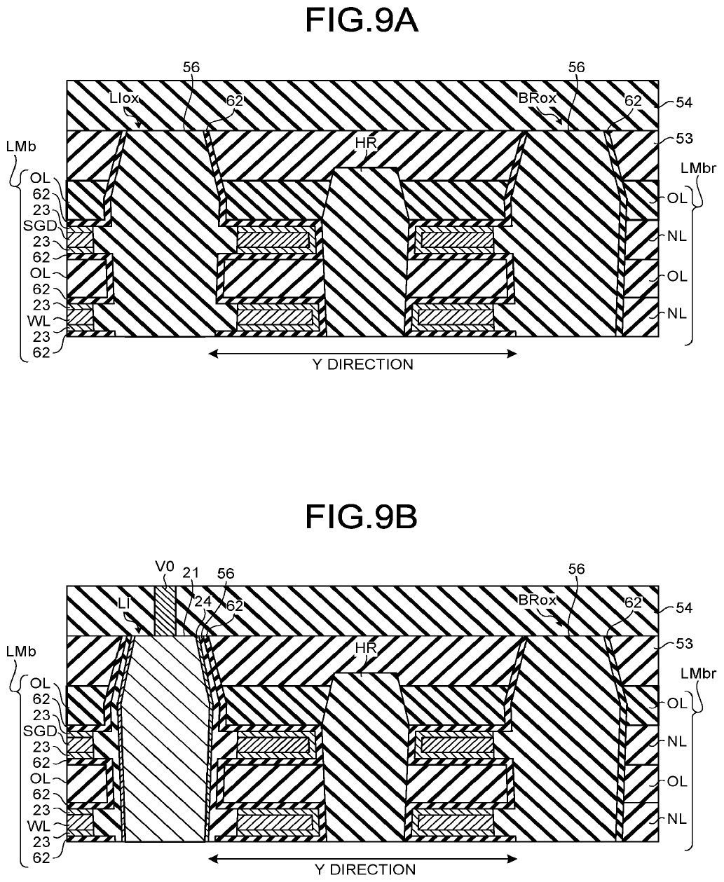

In the first embodiment described above, after the slit ST is used for the replacement process, the conductive layer 21 is filled in the slit ST to form a contact LI functioning as a source-line contact. However, the slit ST may be filled with, for example, an insulating layer 56 to form a configuration that does not contribute to the operation of the semiconductor memory device 1. In this case, it is convenient in the manufacturing process to fill the slit STr with, for example, the insulating layer 56 so as to have a configuration similar to the slit ST. However, in the semiconductor memory device 1, the slits ST and STr may be filled with different materials, and the slits ST and STr may have different configurations from each other. FIGS. 9A and 9B illustrate examples in which at least one of the slits ST and STr is filled with the insulating layer 56 according to modifications of the first embodiment.

In the example of FIG. 9A, the insulating layer 56 is filled in both the slits ST and STr, and a plate-like portion LIox as a second plate-like portion is formed in place of the contact LI, and a plate-like portion BRox as a first plate-like portion is formed in place of the plate-like portion BR. The plate-like portions LIox and BRox do not have a barrier metal layer 24 and a conductive layer 21. The plate-like portion LIox does not function as a source-line contact, and the plug VO is not connected to the plate-like portion LIox.

In the example of FIG. 9B, out of the slits ST and STr, the slit STr is filled with the insulating layer 56, and the plate-like portion BRox is formed in place of the plate-like portion BR. The plate-like portion BRox does not have a barrier metal layer 24 and a conductive layer 21.

In the first embodiment described above, an insulating layer 55 such as a SiO₂ layer is formed on the side wall of the slit STr to be used as a barrier for the replacement process. However, a metal layer such as aluminum or tungsten, a metal oxide layer such as an Al₂O₃ layer, or a conductive layer such as a TiN layer, for example, may be used as a barrier for the replacement process. Thus, using a layer containing a component different from that of the insulating layer OL allows, when the layer is removed from the side wall of the slit STr, a selective ratio with respect to the insulating layer OL to be obtained, and the layer thickness of the insulating layer OL to be easily maintained.

### Second Embodiment

The second embodiment will be described below in detail with reference to the drawings. The method of manufacturing the semiconductor memory device of the second embodiment is different from that of the first embodiment described above. However, also in the second embodiment, the semiconductor memory device 1 substantially identical to the first embodiment is manufactured.

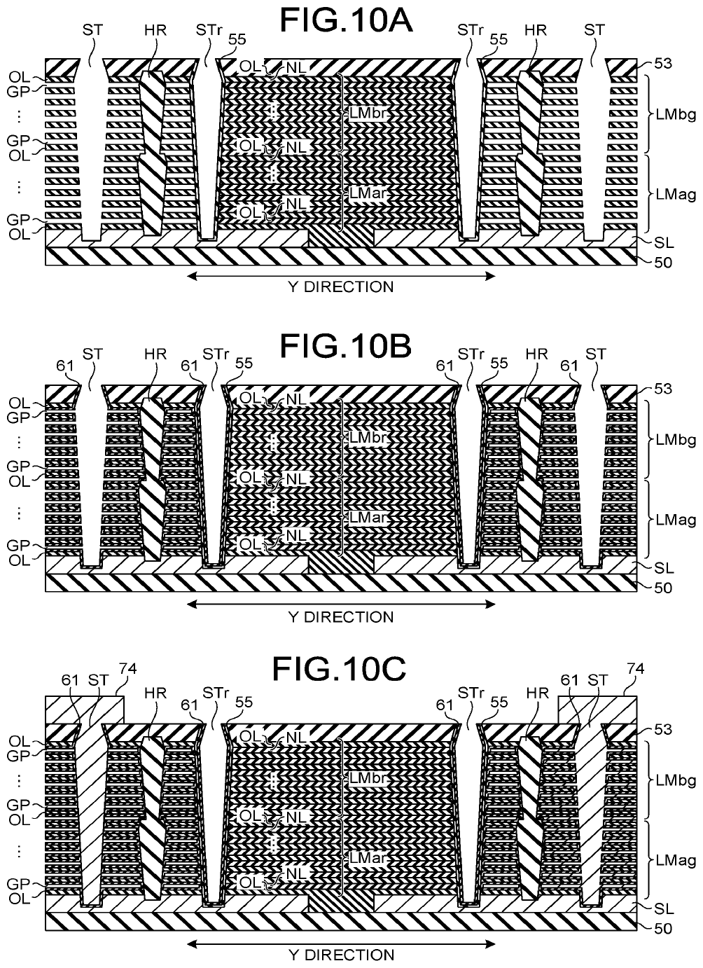

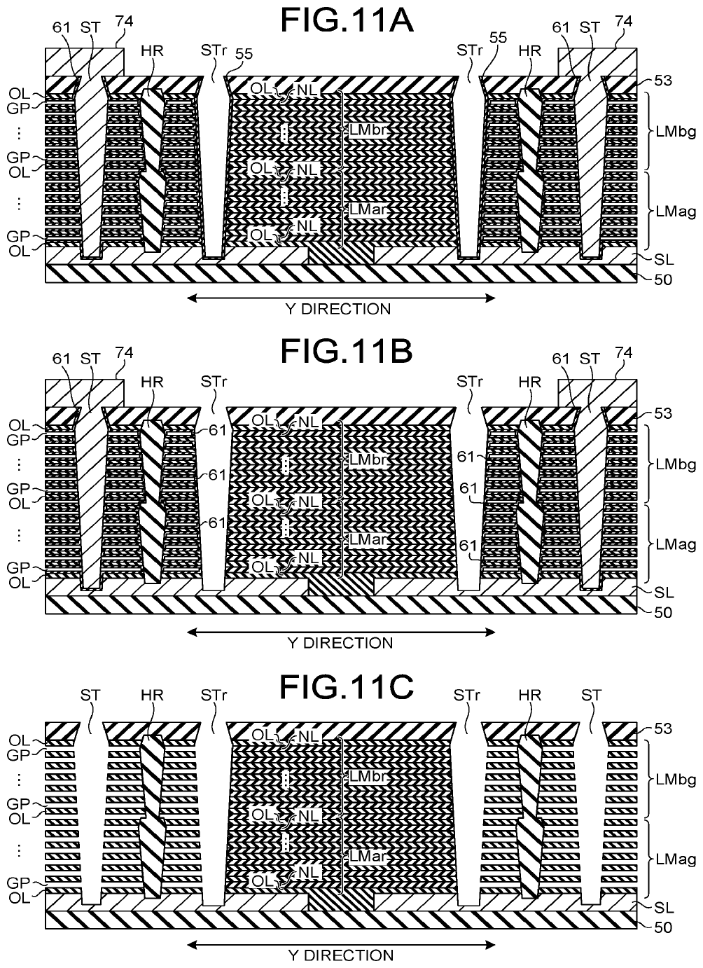

A method of manufacturing the semiconductor memory device 1 according to the second embodiment will be described with reference to FIGS. 10A to 11C. FIGS. 10A to 11C are cross-sectional views along the Y direction illustrating an example of the procedure of the method of manufacturing the semiconductor memory device 1 according to the second embodiment. In FIGS. 10A to 11C, the peripheral circuit CUA is omitted.

In the semiconductor memory device 1 of the second embodiment, the pillar PL and the columnar portion HR are formed in the same manner as, for example, the pillar PL and the columnar portion HR in the first embodiment described above. In the semiconductor memory device 1 of the second embodiment, the processes of FIGS. 6A to 7A of the first embodiment described above are similarly performed when forming the contact LI and the plate-like portion BR.

FIG. 10A illustrates a state after the process of the first embodiment described above in FIG. 7A is performed in the step of forming the contact LI and the plate-like portion BR.

As illustrated in FIG. 10B, a material gas such as an Al₂O₃ layer is made to flow in from the slit ST to form a protective layer 61 on the upper and lower surfaces of the insulating layers OL of the stacked bodies LMag and LMbg.

In such a case, the protective layer 61 is formed over the entire surface of the insulating layer 55 which is disposed on the side wall and the bottom surface of the slit STr and faces the inside of the slit STr. The protective layer 61 is formed on a portion at the height position of the gap GP out of the surface of the insulating layer 55 facing the stacked bodies LMag and LMbg sides. Similarly, the protective layer 61 is formed on the side walls on both sides in the Y direction of the slit ST, that is, on the end surface of the insulating layer 53 and on the end surface of the insulating layer OL of the stacked bodies LMag and LMbg. Further, the protective layer 61 is also formed at a portion of the slit ST in contact with the source line SL, including the bottom surface of the slit. The protective layer 61 is formed on the side surface at the height position of the gap GP of the stacked bodies LMag and LMbg out of the side surface of the columnar portions HR.

As illustrated in FIG. 10C, the slit ST is covered with a resist layer 74.

As illustrated in FIG. 11A, the protective layer 61 in the slit STr is removed, with the slit ST covered with the resist layer 74, to expose the insulating layer 55 in the slit STr.

As illustrated in FIG. 11B, the insulating layer 55 in the slit STr is removed with the slit ST covered with the resist layer 74. In such a case, the upper and lower surfaces of the insulating layers OL of the stacked bodies LMag and LMbg are covered with the protective layer 61. Therefore, erosion of the insulating layer OL in the thickness direction is suppressed.

The removal of the insulating layer 55 in the slit STr allows the protective layer 61 formed at the height position of the gap GP of the stacked bodies LMag and LMbg to be exposed in the slit STr.

As illustrated in FIG. 11C, the resist layer 74 covering the slit ST is removed, and the entire protective film 61 of the stacked bodies LMag and LMbg is removed via both the slits ST and STr. Thus, the protective layer 61 exposed in the slit STr and separating the slit STr from the gap GP is removed, and the slit STr can be communicated with the gaps GP of the stacked bodies LMag and LMbg.

The process in FIG. 7C and the subsequent processes of the first embodiment described above are subsequently performed.

Thus, the semiconductor memory device 1 of the second embodiment is manufactured.

The method of manufacturing the semiconductor memory device 1 according to the second embodiment has the same effect as the method of manufacturing the semiconductor memory device 1 according to the first embodiment.

The method of manufacturing the semiconductor memory device 1 of the second embodiment is to remove the insulating layer 55 on the side wall of the slit STr while the insulating layer OL is protected by the protective layers 61 formed on the upper and lower surfaces of the insulating layer OL. Thus, erosion of the insulating layer OL in the layer thickness direction following the removal of the insulating layer 55 can be suppressed.

The method of manufacturing the semiconductor memory device 1 of the second embodiment is to use, for example, a layer similar to the block layer 62 as the protective layer 61. Thus, the need is eliminated for constructing a new processing technique to form the protective layer 61, and the protective layer 61 can be easily formed.

In second embodiment described above, an Al₂O₃ layer, for example, is used as the protective layer 61. However, as the protective layer 61, for example, a semiconductor layer such as amorphous silicon, a metal layer such as aluminum or tungsten, or a conductive layer such as a TiN layer may be used.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a first stacked body in which a plurality of first conductive layers is stacked via a first insulating layer;
a second stacked body in which a plurality of second insulating layers is stacked via the first insulating layer, the second stacked body being surrounded by the first stacked body as viewed from a stacking direction of each layer of the first stacked body;
a pair of first plate-like portions extending in the stacking direction and in a first direction intersecting the stacking direction, the pair of first plate-like portions being disposed between the first and second stacked bodies on both sides of the second stacked body in a second direction intersecting the stacking direction and the first direction; and
a pair of second plate-like portions extending in the first direction, the pair of second plate-like portions sandwiching the pair of first plate-like portions from both sides in the second direction at a position apart from the pair of first plate-like portions, the pair of second plate-like portions extending in the stacking direction in the first stacked body,
wherein the pair of first plate-like portions each has a first side wall facing the first stacked body and including a metal element-containing layer in contact with an end surface of the first insulating layer of the first stacked body.

2. The semiconductor memory device according to claim 1, wherein the metal element-containing layer extends from the end surface of the first insulating layer and covers both surfaces in the stacking direction of the first insulating layer.

3. The semiconductor memory device according to claim 2, wherein a second conductive layer is interposed between the metal element-containing layer on the surfaces of the first insulating layer and the plurality of first conductive layers of the first stacked body.

4. The semiconductor memory device according to claim 3, wherein the second conductive layer does not extend between the plurality of first conductive layers and the first side wall of each of the pair of first plate-like portions.

5. The semiconductor memory device according to claim 1, wherein
the first side wall further includes a third insulating layer disposed over an entire height position of the plurality of first conductive layers and the first insulating layer of the first stacked body, and
at a height position of the first insulating layer, the metal element-containing layer is interposed between the third insulating layer and the end surface of the first insulating layer.

6. The semiconductor memory device according to claim 5, wherein the third insulating layer is in contact with an end surface of the plurality of first conductive layers at each height position of the plurality of first conductive layers.

7. The semiconductor memory device according to claim 6, wherein
the end surface of the plurality of first conductive layers is located at a position retreated from the pair of first plate-like portions than the end surface of the first insulating layer, and
the third insulating layer protrudes toward the plurality of first conductive layers at each height position of the plurality of first conductive layers.

8. The semiconductor memory device according to claim 1, wherein an inside of the pair of first plate-like portions is filled with a third conductive layer.

9. The semiconductor memory device according to claim 8, wherein an inside of the pair of second plate-like portions is filled with the third conductive layer.

10. The semiconductor memory device according to claim 5, wherein an inside of the pair of first plate-like portions is filled with the third insulating layer.

11. The semiconductor memory device according to claim 10, wherein an inside of the pair of second plate-like portions is filled with the third insulating layer.

12. The semiconductor memory device according to claim 1, wherein the metal element-containing layer comprises a metal oxide.

13. A semiconductor memory device comprising:
a first stacked body in which a plurality of first conductive layers is stacked via a first insulating layer;
a second stacked body in which a plurality of second insulating layers is stacked via the first insulating layer, the second stacked body being surrounded by the first stacked body as viewed from a stacking direction of each layer of the first stacked body;
a pair of first plate-like portions extending in the stacking direction and in a first direction intersecting the stacking direction, the pair of first plate-like portions being disposed between the first and second stacked bodies on both sides of the second stacked body in a second direction intersecting the stacking direction and the first direction; and
a pair of second plate-like portions extending in the first direction, the pair of second plate-like portions sandwiching the pair of first plate-like portions from both sides in the second direction at a position apart from the pair of first plate-like portions, the pair of second plate-like portions extending in the stacking direction in the first stacked body,
wherein the pair of first plate-like portions each has a second side wall facing the second stacked body and
including a metal element-containing layer disposed over an entire height position of the plurality of second insulating layers and the first insulating layer of the second stacked body, the metal element-containing layer being in contact with each end surface of the plurality of second insulating layers and the first insulating layer.

14. The semiconductor memory device according to claim 13, wherein the second side wall further includes a third insulating layer disposed inner side of the metal element-containing layer over the entire height position of the plurality of second insulating layers and the first insulating layer of the second stacked body.

15. The semiconductor memory device according to claim 14, wherein an inside of the pair of first plate-like portions is filled with a third conductive layer.

16. The semiconductor memory device according to claim 15, wherein an inside of the pair of second plate-like portions is filled with the third conductive layer.

17. The semiconductor memory device according to claim 14, wherein an inside of the pair of first plate-like portions is filled with the third insulating layer.

18. The semiconductor memory device according to claim 17, wherein an inside of the pair of second plate-like portions is filled with the third insulating layer.

19. The semiconductor memory device according to claim 13, wherein the metal element-containing layer comprises a metal oxide.

20. A semiconductor memory device comprising:
a first stacked body in which a plurality of first conductive layers is stacked via a first insulating layer;
a second stacked body in which a plurality of second insulating layers is stacked via the first insulating layer, the second stacked body being surrounded by the first stacked body as viewed from a stacking direction of each layer of the first stacked body;
a pair of first plate-like portions extending in the stacking direction and in a first direction intersecting the stacking direction, the pair of first plate-like portions being disposed between the first and second stacked bodies on both sides of the second stacked body in a second direction intersecting the stacking direction and the first direction; and
a pair of second plate-like portions extending in the first direction, the pair of second plate-like portions sandwiching the pair of first plate-like portions from both sides in the second direction at a position apart from the pair of first plate-like portions, the pair of second plate-like portions extending in the stacking direction in the first stacked body,
wherein the pair of first plate-like portions each has a first side wall facing the first stacked body,
the pair of second plate-like portions each has a third side wall facing the first stacked body, and
the first side wall and the third side wall have a same first layer structure as each other at each height position of the plurality of first conductive layers and a same second layer structure as each other at a height position of the first insulating layer.
